(19) United States
(12) Patent Application Publication
(10) Pub. No.: US 2026/0293464 A1
(43) Pub. Date: Sep. 24, 2026

(54) DISPLAY DEVICE AND ELECTRONIC DEVICE INCLUDING THE SAME

(71) Applicant: Samsung Display Co., Ltd., Yongin-si (KR)

(72) Inventors: Yeongmin Lim, Yongin-si (KR); Jeongeun Park, Yongin-si (KR); Chungseok Lee, Yongin-si (KR)

(21) Appl. No.: 19/530,728

(22) Filed: Feb. 5, 2026

(30) Foreign Application Priority Data
Mar. 21, 2025 (KR) 10-2025-0036622

(51) Int. Cl. H10K 59/131; H10K 59/124

(52) U.S. Cl. CPC H10K 59/131; H10K 59/124

(57) ABSTRACT

A display device includes a display panel including a display area and a non-display area including a first non-display area and a second non-display area, and a connection circuit portion electrically connected to the display panel so as to overlap the first non-display area, wherein the display panel includes a substrate, a first inorganic layer which is disposed on the substrate and in which a first groove area is defined, and a first organic layer disposed on the first inorganic layer so as to contact the first inorganic layer, and wherein the first groove area overlaps a first line that is a boundary line between the first non-display area and the second non-display area.

This application claims priority to Korean Patent Application No. 10-2025-0036622, filed on Mar 21, 2025, and all the benefits accruing therefrom under 35 U.S.C. §119, the content of which in its entirety is herein incorporated by reference.

### BACKGROUND

### 1. Field

Embodiments relate to a device, and more particularly, to a display device and an electronic device.

### 2. Description of the Related Art

Mobility-based electronic devices are widely used. As mobile electronic devices, not only compact electronic devices such as mobile phones but also tablet personal computers are being widely used.

To support various functions, such mobile electronic devices include a display device to provide users with visual information such as images or videos. Recently, as other components for driving a display device are miniaturized, the proportion occupied by the display device in an electronic device is being gradually increasing, and structures that enable bending of the display device from a flat state to a predetermined angle are under development.

### SUMMARY

Embodiments include a display device including a display panel having improved adhesion between an inorganic layer and an organic layer.

However, such an objective is merely one among various objectives, and the objective to be solved by the disclosure is not limited thereto.

Additional features will be set forth in part in the description which follows and, in part, will be apparent from the description, or may be learned by practice of the presented embodiments of the disclosure.

In an embodiment of the disclosure, a display device includes a display panel including a display area and a non-display area including a first non-display area and a second non-display area, and a connection circuit portion electrically connected to the display panel so as to overlap the first non-display area, and wherein the display panel includes a substrate, a first inorganic layer disposed on the substrate and defining a first groove area, and a first organic layer disposed on the first inorganic layer so as to contact the first inorganic layer, and wherein the first groove area overlaps a first line that is a boundary line between the first non-display area and the second non-display area.

In an embodiment, the first line may include a first-1 line extending in a first direction parallel to a bending axis along which the connection circuit portion is bent, and a first-2 line extending from the first-1 line in a second direction intersecting the first direction, and the first groove area may overlap the first-2 line.

In an embodiment, the first groove areas may be provided in plural, and a plurality of first groove areas may be spaced apart from each other along the second direction at positions overlapping the first-2 line.

In an embodiment, at least two of the plurality of first groove areas may have different sizes.

In an embodiment, the first groove area may include a first-1 groove area and a first-2 groove area connected to the first-1 groove area.

In an embodiment, the first-1 groove area may be disposed in the first non-display area, and the first-2 groove area may be disposed in the second non-display area.

In an embodiment, the first inorganic layer may further define a second groove area defined inside the first non-display area.

In an embodiment, the display panel may further include a driving transistor disposed on the substrate so as to overlap the display area, and a light-emitting element disposed on the first organic layer so as to overlap the display area and electrically connected to the driving transistor.

In an embodiment, the driving transistor may include a semiconductor layer disposed within the first inorganic layer, and a gate electrode disposed between the first inorganic layer and the first organic layer.

In an embodiment, the display panel may further include a pad portion disposed in the first non-display area so as to be spaced apart from the first groove area and electrically connected to the connection circuit portion.

In an embodiment of the disclosure, an electronic device includes a display panel including a display area and a non-display area including a first non-display area and a second non-display area, and a connection circuit portion electrically connected to the display panel so as to overlap the first non-display area, and wherein the display panel includes a substrate, a first inorganic layer disposed on the substrate and defining a first groove area, and a first organic layer disposed on the first inorganic layer so as to contact the first inorganic layer, and the first groove area is disposed to overlap each of the first non-display area and the second non-display area.

In an embodiment, the first groove area may include a first-1 groove area and a first-2 groove area connected to the first-1 groove area.

In an embodiment, the first-1 groove area may be disposed in the first non-display area, and the first-2 groove area may be disposed in the second non-display area.

In an embodiment, the first inorganic layer may further include a second groove area disposed so as to overlap the first non-display area and not overlap the second non-display area.

In an embodiment, the display panel may further include a driving transistor disposed on the substrate so as to overlap the display area, and a light-emitting element disposed on the first organic layer so as to overlap the display area and electrically connected to the driving transistor.

In an embodiment, the driving transistor may include a semiconductor layer disposed within the first inorganic layer, and a gate electrode disposed between the first inorganic layer and the first organic layer.

In an embodiment, the first groove area may overlap a first line that is a boundary line between the first non-display area and the second non-display area.

In an embodiment, the first line may include a first-1 line extending in a first direction parallel to a bending axis along which the connection circuit portion is bent, and a first-2 line extending from the first-1 line in a second direction intersecting the first direction, and the first groove area may overlap the first-2 line.

In an embodiment, the first groove areas may be provided in plural, and a plurality of first groove areas may be spaced apart from each other along the second direction at positions overlapping the first-2 line.

In an embodiment, the display panel may further include a pad portion disposed in the first non-display area so as to be spaced apart from the first groove area and electrically connected to the connection circuit portion.

Other features and advantages than those described above will become apparent from the following drawings, claims, and detailed description of the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIGS. 1 and 2 are plan views schematically illustrating an embodiment of a display device;

FIG. 3 is a perspective view schematically illustrating an embodiment of a display panel;

FIG. 4 is a cross-sectional view schematically illustrating an embodiment of a display device;

FIGS. 5 and 6 are cross-sectional views schematically illustrating an embodiment of a display panel;

FIGS. 7 and 8 are equivalent circuit diagrams of an embodiment of a pixel which may be provided in the display panel of FIG. 1;

FIG. 9 is a cross-sectional view schematically illustrating an embodiment of a portion of a display panel;

FIGS. 10 and 11 are cross-sectional views schematically illustrating an embodiment of a portion of a display device;

FIGS. 12 and 13 are plan views schematically illustrating an embodiment of a portion of a display device;

FIG. 14 is a cross-sectional view schematically illustrating an embodiment of a portion of a display device;

FIG. 15 is a block diagram of an embodiment of an electronic device; and

FIG. 16 is a perspective view schematically illustrating an embodiment of an electronic device.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term "and/or" may include any and all combinations of one or more of the associated listed items. Throughout the disclosure, the expression "at least one of a, b or c" indicates only a, only b, only c, both a and b, both a and c, both b and c, all of a, b, and c, or variations thereof.

As the disclosure allows for various changes and numerous embodiments, illustrative embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

Although the terms "first," "second,", “first_1” (e.g., referring to a first part of a first element), “first_2” (e.g., referring to a second part of the first element), etc., may be used to describe various elements, these elements should not be limited by these terms. These terms are only used to distinguish one element from another.

As used herein, the singular forms "a," "an," and "the" are intended to include the plural forms as well, unless the context clearly indicates otherwise.

It will be understood that the terms "including" and "having" are intended to indicate the existence of the features or elements described in the specification, and are not intended to preclude the possibility that one or more other features or elements may exist or may be added.

It will be further understood that, when a layer, region, or component is referred to as being "on" another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

When an illustrative embodiment may be implemented differently, a predetermined process order may be different from the described order. For example, two consecutively described processes may be performed substantially at the same time or may be performed in an order opposite to the described order.

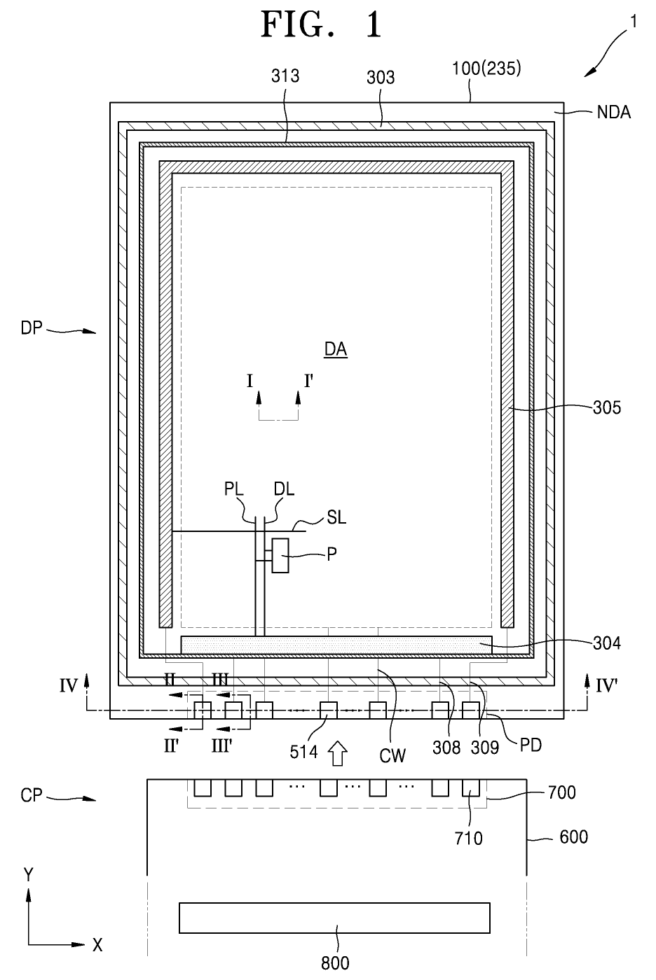

In the specification, a "plan view" refers to a two-dimensional view seen in a direction perpendicular to a substrate 100 (refer to FIG. 1). That is, "A and B spaced apart from each other in a plan view" means "A and B spaced apart from each other when viewed in a direction perpendicular to the substrate 100 (refer to FIG. 1). "

In the specification, a "cross-sectional view" refers to a two-dimensional view cut in a direction perpendicular to the substrate 100 (refer to FIG. 1). That is, "A and B spaced apart from each other in a cross-sectional view" means "A and B spaced apart from each other in a two-dimensional view cut in a direction perpendicular to the substrate 100 (refer to FIG. 1). "

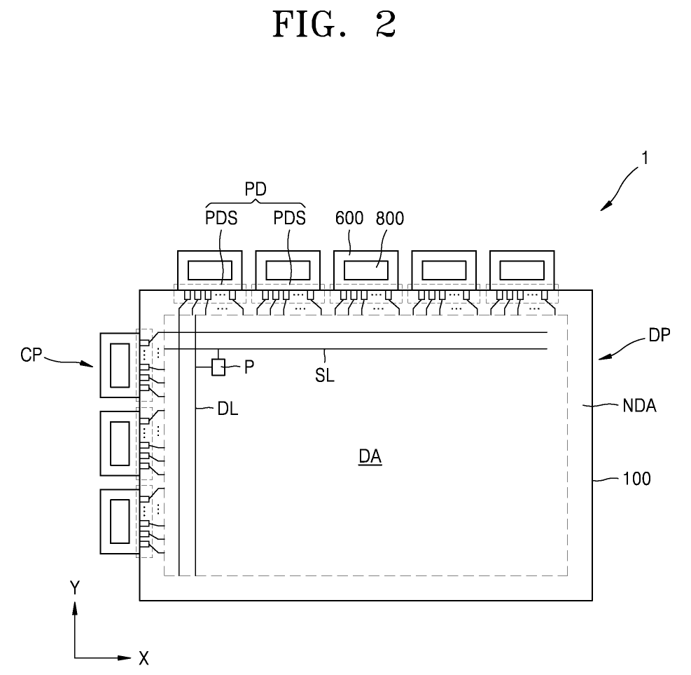

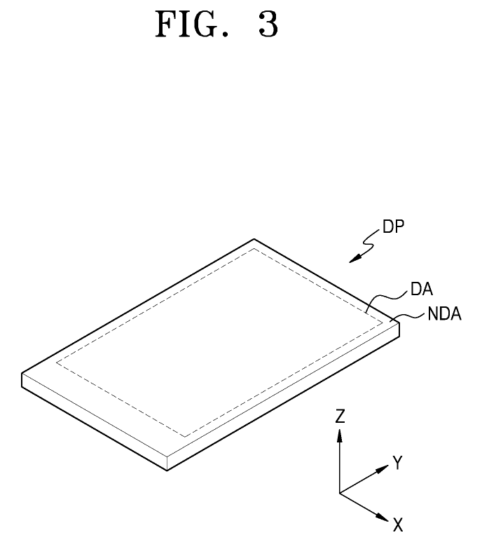

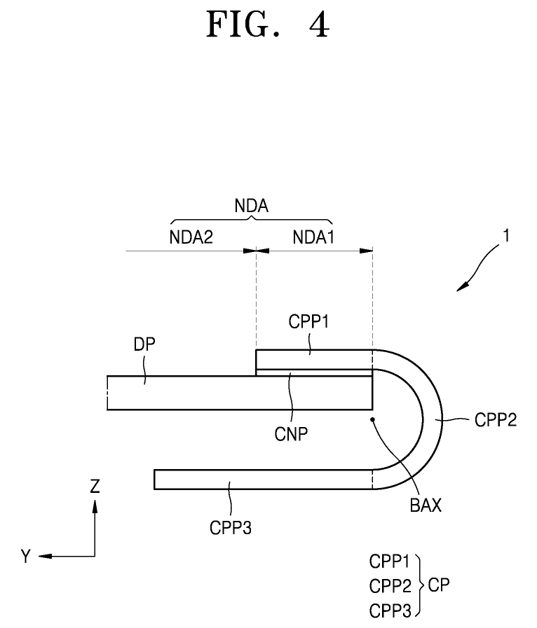

FIGS. 1 and 2 are plan views schematically illustrating an embodiment of a display device 1, FIG. 3 is a perspective view schematically illustrating an embodiment of a display panel DP, and FIG. 4 is a cross-sectional view schematically illustrating the display device 1.

Referring to FIGS. 1 to 4, the display device 1 may include the display panel DP, a connection circuit portion CP, and a connection portion CNP.

The display panel DP may include a display area DA and a non-display area NDA extending outside the display area DA. The display panel DP may display an image through the display area DA. The display panel DP is described as one of the embodiments as an organic light-emitting display device, but the display device of the disclosure is not limited thereto. In an embodiment, the display panel DP may include an inorganic light-emitting display device or a quantum dot light-emitting display device. An emission layer of a light-emitting element (e.g., light-emitting diode) provided in the display panel DP may include an organic material, an inorganic material, a quantum dot, an organic material and a quantum dot, or an inorganic material and a quantum dot.

The display device 1 includes a substrate 100 and an encapsulation substrate 235. A seal portion 303 may be disposed between the substrate 100 and the encapsulation substrate 235. The seal portion 303 surrounds the periphery of the substrate 100 and the encapsulation substrate 235, and may bond the substrate 100 and the encapsulation substrate 235 together.

The display device 1 includes the display area DA and the non-display area NDA extending around the display area DA. The display device 1 may provide images by light emitted from a plurality of pixels P disposed in the display area DA.

The display area DA may include the plurality of pixels P connected to a scan line SL extending in a first direction (e.g., an x-axis direction) and a data line DL extending in a second direction (e.g., a y-axis direction) intersecting the first direction (e.g., the x-axis direction). Each pixel P may also be connected to a driving voltage line PL extending in the second direction (e.g., the y-axis direction).

Each of the plurality of pixels P may include a light-emitting element, e.g., a light-emitting diode such as an organic light-emitting diode OLED. In an embodiment, each pixel P may emit red, green, blue, or white light via the organic light-emitting diode OLED, for example. In an embodiment, the organic light-emitting diode OLED included in multiple pixels P all emit the same color, and the color of each pixel P may be implemented by a color filter or the like disposed on top of the organic light-emitting diode OLED, for example.

Each pixel P may be electrically connected to multiple built-in circuits disposed in the non-display area NDA. In an embodiment, a first power supply wire 304, a second power supply wire 305, and a pad portion PD may be disposed in the non-display area NDA, for example.

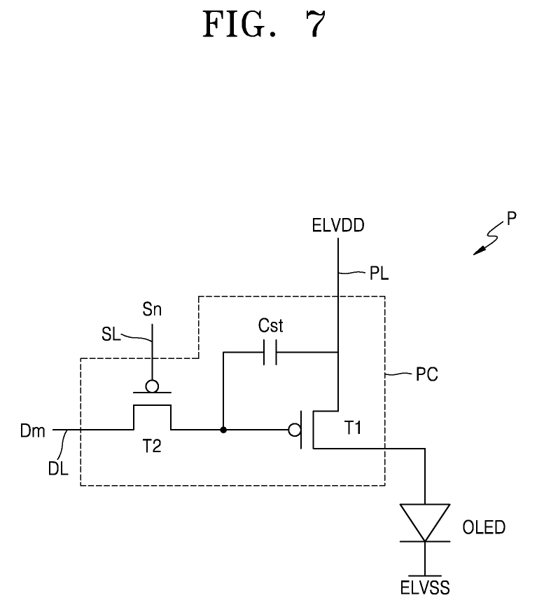

The first power supply wire 304 may be disposed on one side of the display area DA, e.g., at the bottom of the display device 1. The first power supply wire 304 may be connected to the plurality of driving voltage lines PL that transmit a driving voltage ELVDD (refer to FIG. 7) to the pixel P. The second power supply wire 305 may partially surround the display area DA in a loop shape with one side open. The second power supply wire 305 may provide a common voltage ELVSS (refer to FIG. 7) to a counter electrode of the pixel P.

The pad portion PD has a plurality of pad terminals 514 and may be disposed in the non-display area NDA of the substrate 100. Each pad terminal 514 may be connected to a first connection wire 308 connected to the first power supply wire 304 or may be connected to a connection wire CW extending to the display area DA. Each pad terminal 514 may be electrically connected to a connection circuit board 600. A driving terminal portion 700 of the connection circuit board 600 may be electrically connected to the pad portion PD. The driving terminal portion 700 may include a plurality of driving terminals 710. The plurality of driving terminals 710 may be electrically connected to the plurality of corresponding pad terminals 514.

The connection circuit board 600 may transmit a signal or power from a control unit (not shown) to the pad portion PD. The control unit may provide the driving voltage ELVDD (refer to FIG. 7) to the first power supply wire 304 via the first connection wire 308. The control unit may provide the common voltage ELVSS (refer to FIG. 7) to the second power supply wire 305 via a second connection wire 309.

A data driving circuit portion 800 is electrically connected to the data line DL. A data signal of the data driving circuit portion 800 may be provided to each pixel P through the connection wire CW connected to the pad portion PD and the data line DL connected to the connection wire CW. FIG. 1 illustrates that the data driving circuit portion 800 is disposed on the connection circuit board 600, but in another embodiment, the data driving circuit portion 800 may be disposed on the substrate 100. In an embodiment, the data driving circuit portion 800 may be disposed between the pad portion PD and the first power supply wire 304, for example.

A dam portion 313 may be disposed in the non-display area NDA. The dam portion 313 may prevent an organic material from flowing in a direction toward an edge of the substrate 100 when an organic encapsulation layer of a thin-film encapsulation layer is formed, so as to prevent the formation of an edge tail of the organic encapsulation layer. The dam portion 313 may surround at least a portion of the display area DA. The dam portion 313 may include a plurality of dams. When the dam portion 313 may include the plurality of dams, the respective dams may be disposed apart from each other. The dam portion 313 may be disposed closer to the display area DA than the seal portion 303.

FIG. 1 illustrates that one connection circuit board 600 is attached to the pad portion PD, but as shown in FIG. 2, a plurality of connection circuit boards 600 may be attached to the pad portion PD. The pad portion PD may be disposed along two sides of the substrate 100. The pad portion PD may include a plurality of sub-pad portions PDS, and each connection circuit board 600 may be attached to each of the sub-pad portions PDS.

Referring to FIG. 4, the connection circuit portion CP may include a first portion CPP1 fixed to the display panel DP, a second portion CPP2 bent around a bending axis BAX, and a third portion CPP3 disposed at the bottom of the display panel DP. The non-display area NDA may include a first non-display area NDA1 that overlaps the connection circuit portion CP, and a second non-display area NDA2 that does not overlap the connection circuit portion CP. In the first non-display area NDA1, the connection portion CNP may fix together the display panel DP and the first portion CPP1 of the connection circuit portion CP. As the second portion CPP2 is bent, the third portion CPP3 may be disposed at the bottom side of the display panel DP. However, as the second portion CPP2 is bent, elastic force of the second portion CPP2 may be transmitted to the display panel DP. Therefore, stress may occur in the first non-display area NDA of the display panel DP.

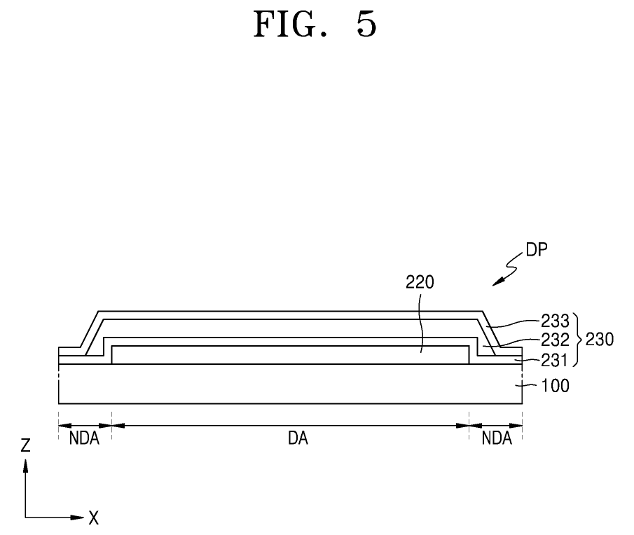

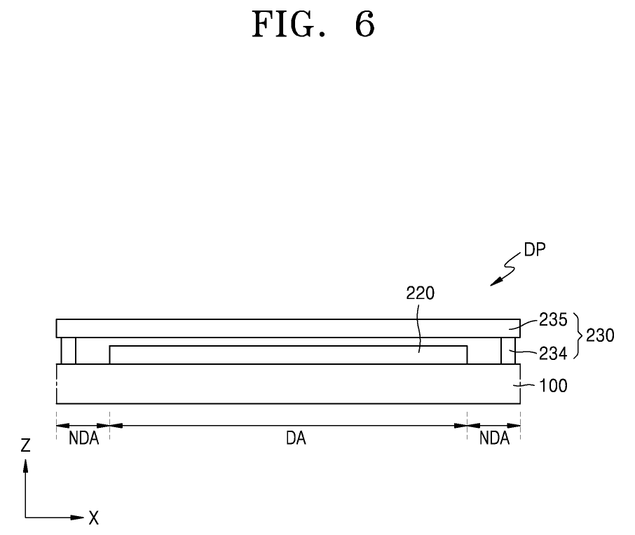

FIGS. 5 and 6 are cross-sectional views schematically illustrating an embodiment of the display panel DP.

Referring to FIG. 5, the display panel DP includes the substrate 100, a display element layer 220 on the substrate 100, and an encapsulation member 230 covering the display element layer 220.

The substrate 100 may include polymer resin. The substrate 100 may have a single-layer or multi-layer structure, and in the case of a multi-layer structure, the substrate 100 may further include an inorganic layer (not shown). The substrate 100 may have flexible, rollable, or bendable properties.

The display element layer 220 includes a plurality of pixels, and each pixel may include an organic light-emitting diode and a pixel circuit electrically connected to the organic light-emitting diode. The pixel circuit may include transistors, storage capacitors, and conductive lines connected thereto, and may include insulating layers.

The encapsulation member 230 may protect the display element layer 220 from foreign substances such as moisture. The encapsulation member 230 may be a thin-film encapsulation layer including at least one inorganic encapsulation layer 231 or 233 (hereinafter also referred to as the first inorganic encapsulation layer 231 or the second inorganic encapsulation layer 233) and at least one organic encapsulation layer 232

The encapsulation member 230 of FIG. 5 includes the first inorganic encapsulation layer 231, the second inorganic encapsulation layer 233, and the organic encapsulation layer 232 disposed therebetween, but the disclosure is not limited thereto. The stacking order of the inorganic encapsulation layers 231 and 233 and the organic encapsulation layer 232 may be changed in various ways. The encapsulation member 230 of FIG. 5 is illustrated as a thin-film encapsulation layer, but the disclosure is not limited thereto.

Referring to FIG. 6, the display panel DP may include the substrate 100, the display element layer 220 on the substrate 100, and the encapsulation member 230 including the seal portion 234 and the encapsulation substrate 235. The substrate 100 of FIG. 6 may include glass, or polymer resin.

The encapsulation substrate 235 is disposed facing the substrate 100, and the seal portion 234 may be disposed between the substrate 100 and the encapsulation substrate 235. The seal portion 234 may surround the display area DA. An inner space defined by the substrate 100, the encapsulation substrate 235, and the seal portion 234 is spatially separated from the outside, and may prevent intrusion of moisture or impurities. The encapsulation substrate 235 may include glass, polymer resin, etc., and the seal portion 234 may use a material such as frit or epoxy.

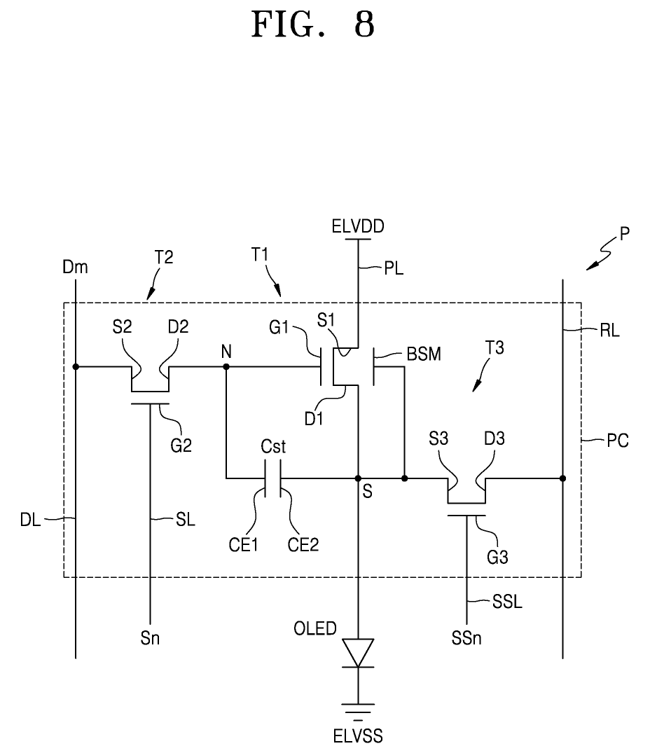

FIGS. 7 and 8 are equivalent circuit diagrams of an embodiment of the pixel P that may be provided in the display panel DP of FIG. 1.

Referring to FIG. 7, each pixel P includes the pixel circuit PC connected to the scan line SL and the data line DL, and the organic light-emitting diode OLED connected to the pixel circuit PC.

The pixel circuit PC includes a driving transistor T1, a switching transistor T2, and a storage capacitor Cst. The switching transistor T2 is connected to the scan line SL and the data line DL, and transmits the data signal Dm input through the data line DL to the driving transistor T1 according to a scan signal Sn input through the scan line SL.

The storage capacitor Cst is connected to the switching transistor T2 and the driving voltage line PL, and stores a voltage corresponding to the difference between the voltage received from the switching transistor T2 and the driving voltage ELVDD supplied to the driving voltage line PL.

The driving transistor T1 is connected to the driving voltage line PL and the storage capacitor Cst, and in response to a value of voltage stored in the storage capacitor Cst, may control a driving current flowing through the organic light-emitting diode OLED from the driving voltage line PL. The organic light-emitting diode OLED may emit light having a predetermined brightness according to the driving current.

FIG. 7 illustrates a case where the pixel circuit PC includes two transistors and one storage capacitor, but the disclosure is not limited thereto.

Referring to FIG. 8, each pixel P may include the organic light-emitting diode OLED and the pixel circuit PC including a plurality of transistors for controlling the organic light-emitting diode OLED. The pixel circuit PC may include the driving transistor T1, the switching transistor T2, a sensing transistor T3, and the storage capacitor Cst.

The scan line SL may be connected to a gate electrode G2 of the switching transistor T2, the data line DL may be connected to a source electrode S2, and a first electrode CE1 of the storage capacitor Cst may be connected to a drain electrode D2. Accordingly, the switching transistor T2 supplies a data voltage of the data line DL to a first node N, in response to the scan signal Sn from the scan line SL of each pixel P.

A gate electrode G1 of the driving transistor T1 is connected to the first node N, a source electrode S1 is connected to the driving voltage line PL that transmits the driving voltage ELVDD, and a drain electrode D1 may be connected to a pixel electrode (e.g., an anode electrode) of the organic light-emitting diode OLED. Accordingly, the driving transistor T1 may adjust a current amount flowing in the organic light-emitting diode OLED according to a source-gate voltage, that is, a voltage applied between the driving voltage ELVDD and the first node N.

A sensing control line SSL may be connected to a gate electrode G3 of the sensing transistor T3, a source electrode S3 may be connected to a second node S, and a drain electrode D3 may be connected to a reference voltage line RL. In some embodiments, the sensing transistor T3 may be controlled by the scan line SL, instead of the sensing control line SSL.

The sensing transistor T3 may sense a potential of the pixel electrode (e.g., the anode electrode) of the organic light-emitting diode OLED. The sensing transistor T3 supplies a pre-charging voltage from the reference voltage line RL to the second node S, in response to a sensing signal SSn from the sensing control line SSL, or supplies a voltage of the pixel electrode (e.g., the anode electrode) of the organic light-emitting diode OLED to the reference voltage line RL during a sensing period.

The storage capacitor Cst has the first electrode CE1 connected to the first node N and a second electrode CE2 connected to the second node S. The storage capacitor Cst charges a difference voltage between voltages supplied to each of the first and second nodes N and S and supplies the difference voltage as the driving voltage of the driving transistor T1. In an embodiment, the storage capacitor Cst may charge a differential voltage between the data signal Dm and a precharging voltage supplied to each of the first and second nodes N and S, for example.

A bias electrode BSM is formed to correspond to the driving transistor T1 and may be connected to the source electrode S3 of the sensing transistor T3. The bias electrode BSM receives a voltage in conjunction with a potential of the source electrode S3 of the sensing transistor T3, and thereby the driving transistor T1 is stabilized. In some embodiments, the bias electrode BSM may be connected to a separate bias wire, not to the source electrode S3 of the sensing transistor T3.

The counter electrode, e.g., a cathode electrode, of the organic light-emitting diode OLED may receive the common voltage ELVSS. The organic light-emitting diode OLED emits light upon receiving the driving current from the driving transistor T1.

Although FIG. 8 illustrates a case in which the signal lines SL, SSL and DL, the reference voltage line RL, and the driving voltage line PL are provided for each pixel P, the disclosure is not limited thereto. In an embodiment, at least one of the signal lines SL, SSL and DL, and/or the reference voltage line RL and the driving voltage line PL may be shared with a neighboring pixel, for example.

The pixel circuit PC is not limited to the number and circuit design of the transistor and the storage capacitor described with reference to FIGS. 7 and 8, and the number and circuit design thereof may be variously changed.

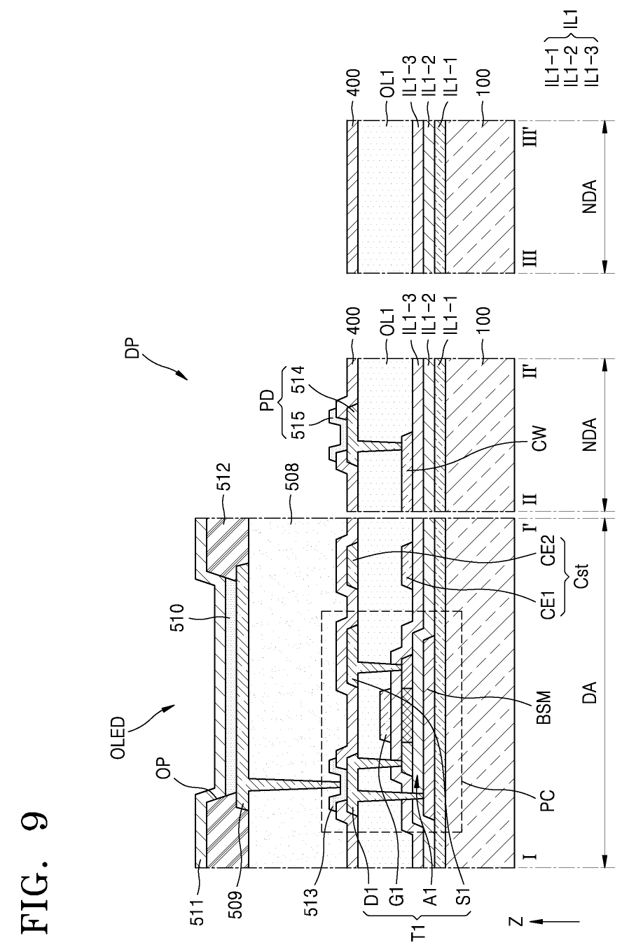

FIG. 9 is a cross-sectional view schematically illustrating an embodiment of a portion of the display panel DP.

In detail, FIG. 9 is a cross-sectional view of the display panel DP according to lines I-I', II-II', and III-III' of FIG. 1. FIG. 9 illustrates the driving transistor T1 and the storage capacitor Cst among the pixel circuit PC described with reference to FIG. 7.

Referring to FIG. 9, the display panel DP includes the substrate 100. The substrate 100 may include a material such as glass, ceramic, metal, or polymer. A first inorganic layer IL1 may be disposed on the substrate 100. The first inorganic layer IL1 may include a first-1 inorganic layer IL1-1, a first-2 inorganic layer IL1-2, and a first-3 inorganic layer IL1-3.

The first-1 inorganic layer IL1-1 may be disposed on the substrate 100. The first-1 inorganic layer IL1-1 may block foreign substances or moisture penetrating through the substrate 100. In an embodiment, the first-1 inorganic layer IL1-1 may include an inorganic material such as silicon oxide, silicon nitride, or silicon oxynitride, and may include a single layer or multiple layers, for example.

The bias electrode BSM may be disposed on the first-1 inorganic layer IL1-1. The driving transistor T1 may be disposed on the substrate 100 so as to overlap the display area DA. In detail, the driving transistor T1 may be disposed on the bias electrode BSM. The bias electrode BSM may overlap a semiconductor layer A1 of the driving transistor T1. A voltage may be applied to the bias electrode BSM. In an embodiment, the bias electrode BSM may be connected to the source electrode S3 (refer to FIG. 8) of the sensing transistor T3 (refer to FIG. 8), so that a voltage of the source electrode S3 may be applied, for example. Additionally, the bias electrode BSM may block external light from reaching the semiconductor layer A1. Accordingly, the characteristics of the driving transistor T1 may be stabilized. In another embodiment, the bias electrode BSM may be omitted.

The first-2 inorganic layer IL1-2 may cover the bias electrode BSM. The first-2 inorganic layer IL1-2 may be disposed throughout the entirety of the area of the substrate 100. The first-2 inorganic layer IL1-2 may include inorganic materials such as silicon oxide, silicon nitride, and silicon oxynitride, and may be a single layer or multiple layers.

The semiconductor layer A1 may be disposed on the first-2 inorganic layer IL1-2. The semiconductor layer A1 may include polysilicon, amorphous silicon, an oxide semiconductor, organic semiconductor material, etc. In an embodiment, the semiconductor layer A1 may include a channel region overlapping the gate electrode G1, and a source region and a drain region which are disposed on opposite sides of the channel region and include or consist of a higher concentration of impurities than the channel region. The impurities may include N-type impurities or P-type impurities.

The first-3 inorganic layer IL1-3 may cover the semiconductor layer A1. That is, the semiconductor layer A1 may be disposed inside the first inorganic layer IL1. The first-3 inorganic layer IL1-3 may be an inorganic layer such as silicon nitride, silicon oxide, or silicon nitride, and may be a single layer or multiple layers. The gate electrode G1 may be disposed on the first-3 inorganic layer IL1-3. The gate electrode G1 may include molybdenum (Mo), aluminum (Al), copper (Cu), titanium (Ti), etc. The gate electrode G1 may be a single layer or a multilayer.

A first organic layer OL1 may be disposed on the first inorganic layer IL1 so as to contact the first inorganic layer IL1. The first electrode CE1 of the storage capacitor Cst may be disposed in a same layer as the gate electrode G1. The first electrode CE1 may include a same material as that of the gate electrode G1. The first organic layer OL1 may cover the gate electrode G1 and the first electrode CE1 of the storage capacitor Cst. That is, the gate electrode G1 may be disposed between the first inorganic layer IL1 and the first organic layer OL1. The first organic layer OL1 may be an inorganic layer such as silicon nitride, silicon oxide, or silicon nitride. The first organic layer OL1 may be single-layered or multi-layered.

The source electrode S1, the drain electrode D1, the second electrode CE2 of the storage capacitor Cst, and the driving voltage line PL may be disposed on the first organic layer OL1. The source electrode S1, the drain electrode D1, the second electrode CE2 of the storage capacitor Cst, and the driving voltage line PL may include Al, Cu, Ti, etc., and may each be a single layer or a multilayer. In an embodiment, the source electrode S1, the drain electrode D1, the second electrode CE2 of the storage capacitor Cst, and the driving voltage line PL may have a multi-layer structure of Ti/Al/Ti. The source electrode S1 and the drain electrode D1 may be connected to the source region and the drain region of the semiconductor layer A1, respectively, through contact holes. The source electrode S1 may be connected to the driving voltage line PL.

The second electrode CE2 of the storage capacitor Cst overlaps the first electrode CE1 with the first organic layer OL1 disposed therebetween, and may form capacitance. In this case, the first organic layer OL1 may function as a dielectric layer of the storage capacitor Cst. The thickness of the first organic layer OL1 may be designed according to the value of the capacitance of the storage capacitor Cst.

A protective layer 400 may cover the source electrode S1, the drain electrode D1, the second electrode CE2 of the storage capacitor Cst, and the driving voltage line PL. The protective layer 400 may be an inorganic layer such as silicon nitride, silicon oxide, or silicon nitride. The protective layer 400 may protect the conductive layer or wires disposed on the first organic layer OL1.

In the display area DA, a planarization layer 508 may be disposed on the protective layer 400. The planarization layer 508 may include an organic material, and the organic material may include imide-based polymer, general purpose polymer such as polymethylmethacrylate or polystyrene, polymer derivatives having a phenolic group, acryl-based polymer, arylether-based polymer, amide-based polymer, fluorine-based polymer, p-xylene-based polymer, vinyl alcohol-based polymer, or any combinations thereof. In an embodiment, the planarization layer 508 may include polyimide.

When the protective layer 400 having an inorganic material is absent, a conductive layer or wire such as the driving voltage line PL may be oxidized or corroded by reacting with oxygen intruding from the planarization layer 508. However, as the embodiment may include the protective layer 400, the conductive layer or wire such as the driving voltage line PL may not directly contact the planarization layer 508.

The organic light-emitting diode OLED is disposed on the first organic layer OL1 so as to overlap the display area DA and may be electrically connected to the driving transistor T1. In detail, the organic light-emitting diode OLED may be disposed on the planarization layer 508. The organic light-emitting diode OLED includes the pixel electrode 509, an intermediate layer 510 including the emission layer, and the counter electrode 511.

The pixel electrode 509 may be electrically connected to the drain electrode D1 through a contact hole penetrating the planarization layer 508. The pixel electrode 509 may be connected to the drain electrode D1 via a first conductive protective layer 513. The first conductive protective layer 513 may cover the drain electrode D1. The first conductive protective layer 513 may be a metal layer to prevent damage to the drain electrode D1.

The pixel electrode 509 may be a (semi)transparent electrode or a reflective electrode. In an embodiment, the pixel electrode 509 may have a reflective layer including Ag, Mg, Al, Pt, Pd, Au, Ni, Nd, Ir, Cr, or any combinations thereof, and a transparent or semitransparent electrode layer disposed on the reflective layer. The transparent or semi-transparent electrode layer may include at least one material selected from the group including or consisting of indium tin oxide (“ITO”), indium zinc oxide (“IZO”), zinc oxide (ZnO), indium oxide (In₂O₃), indium gallium oxide (“IGO”), and aluminum zinc oxide (“AZO”). In an embodiment, the pixel electrode 509 may be ITO/Ag/ITO.

A bank layer 512 may be disposed on the planarization layer 508. The bank layer 512 defines an opening OP that exposes a portion of the pixel electrode 509, and a light-emitting area may be defined by the opening OP. The bank layer 512 may be an organic material such as polyimide or hexamethyldisiloxane.

The intermediate layer 510 may include the emission layer. Functional layers such as a hole transport layer, a hole injection layer, an electron transport layer, and an electron injection layer may be optionally further disposed below and above the emission layer. The emission layer may include a low-molecular-weight organic material or a polymer organic material.

When the emission layer may include a low-molecular-weight organic material, the intermediate layer 510 may be stacked in a single or composite structure including the hole injection layer, the hole transport layer, the emission layer, the electron transport layer, the electron injection layer, etc. The low-molecular-weight organic material may include various organic materials including copper phthalocyanine (“CuPc”), N,N'-Di(napthalene-1-yl)-N,N'-diphenyl-benzidine, tris-8-hydroxyquinoline aluminum (“Alq3”), or the like. The emission layer may be formed in a vacuum deposition method.

When the emission layer may include a polymer organic material, the intermediate layer 510 may have a structure including the hole transport layer and the emission layer. The emission layer may include a polymer material based on poly-phenylene vinylene (“PPV”), polyfluorene, or the like. The emission layer may be formed by a screen printing, inkjet printing, a laser induced thermal imaging (“LITI”), or the like.

The counter electrode 511 may be a light-transmitting electrode or a reflective electrode. In an embodiment, the counter electrode 511 may be a transparent or semi-transparent electrode, and may include a metal thin film having a relatively low work function and including Li, Ca, LiF/Ca, LiF/Al, Al, Ag, Mg, and any combinations thereof. Furthermore, a transparent conductive oxide (“TCO”) film such as ITO, IZO, ZnO, In₂O₃, or the like may be further disposed on the metal thin film. The counter electrode 511 may extend not only to the display area DA, but also to the non-display area NDA outside the display area DA as shown in FIG. 1. The counter electrode 511 may be disposed on the intermediate layer 510.

In the non-display area NDA, the connection wire CW may be disposed on the first inorganic layer IL1 (in detail, the first-3 inorganic layer IL1-3). The connection wire CW may extend to the display area DA. The connection wire CW may include a same material as that of the gate electrode G1. The first organic layer OL1 may cover the connection wire CW.

The pad portion PD may include the pad terminal 514 and a conductive protective layer 515. The pad terminal 514 may be disposed on the first organic layer OL1. The pad terminal 514 may be electrically connected to the connection wire CW through a contact hole. The pad terminal 514 may include Al, Cu, Ti, etc., and may be single layer or multilayer. The protective layer 400 may cover an edge of the pad terminal 514. The conductive protective layer 515 may cover an upper surface of the exposed pad terminal 514. The conductive protective layer 515 may include metal having a lower degree of oxidation than the material included in the pad terminal 514, or having superior anti-corrosion properties. In an embodiment, a top layer of the pad terminal 514 may include Cu, and the conductive protective layer 515 may include Ti.

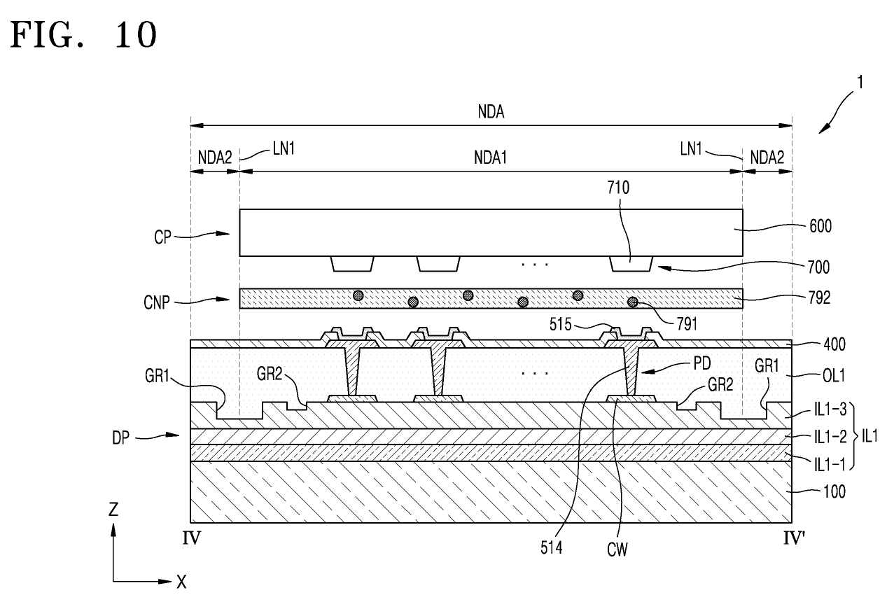

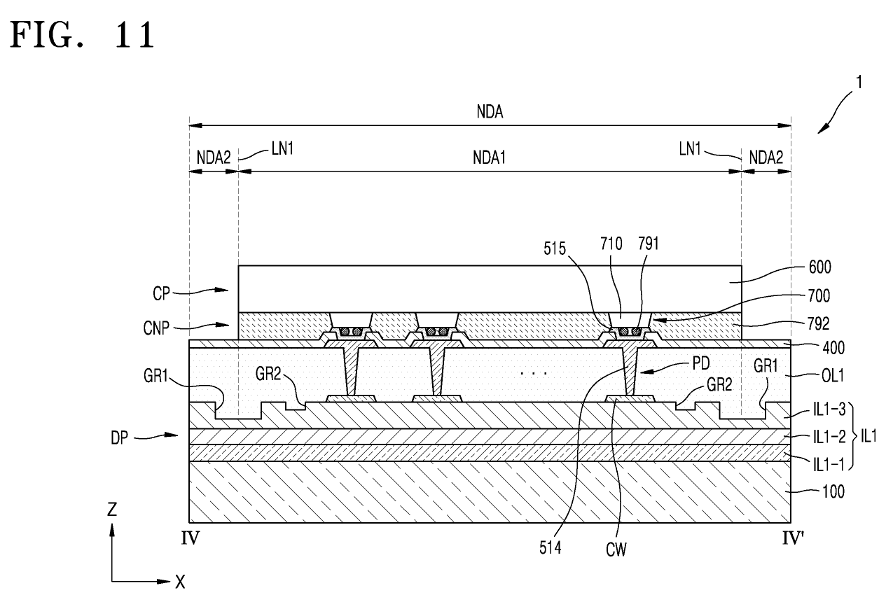

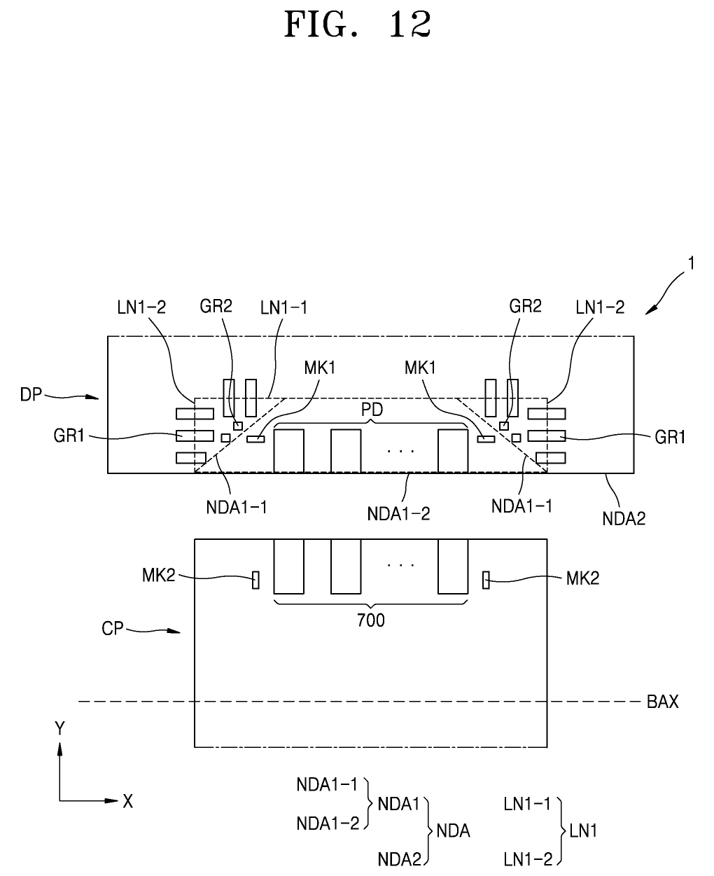

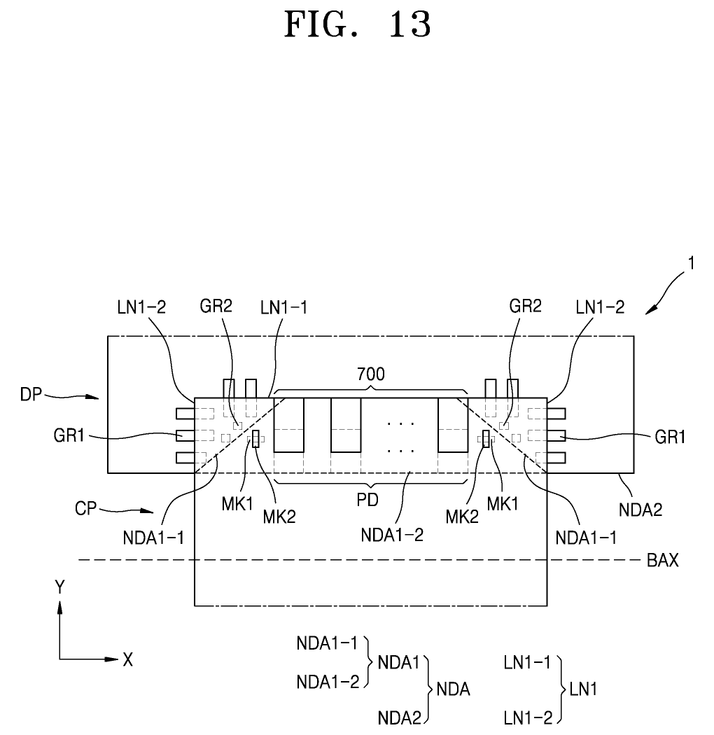

FIGS. 10 and 11 are cross-sectional views schematically illustrating an embodiment of a portion of the display device 1, FIGS. 12 and 13 are plan views schematically illustrating an embodiment of a portion of the display device 1.

In detail, FIGS. 10 and 11 are cross-sectional views of the display device 1 along line IV-IV' of FIG. 1. FIGS. 10 and 12 are drawings showing a state before the connection circuit portion CP is connected to the display panel DP, and FIGS. 11 and 13 are drawings showing a state in which the connection circuit portion CP is connected to the display panel DP.

Referring to FIGS. 10 to 13, the display device 1 may include the display panel DP, the connection circuit portion CP, and the connection portion CNP.

The non-display area NDA may include the first non-display area NDA1 and the second non-display area NDA2. The first non-display area NDA1 may be an area overlapping the connection circuit portion CP when the display panel DP and the connection circuit portion CP are connected to each other. That is, the connection circuit portion CP may be electrically connected to the display panel DP so as to overlap the first non-display area NDA1. Additionally, the connection portion CNP may overlap the first non-display area NDA1.

The second non-display area NDA2 may be an area that does not overlap the connection circuit portion CP, when the display panel DP and the connection circuit portion CP are connected to each other. In FIGS. 12 and 13, the plane shape of the first non-display area NDA1 is illustrated as being a square, but this is only an illustrative embodiment and the shape of the first non-display area NDA1 is not limited thereto.

In a plan view, a boundary between the first non-display area NDA1 and the second non-display area NDA2 may be defined as a first line LN1. The first line LN1 may include a first-1 line LN1-1 extending in the first direction (e.g., the x-axis direction) parallel to the bending axis BAX of the connection circuit portion CP, and a first-2 line LN1-2 extending in the second direction (e.g., the y-axis direction). As shown in FIGS. 12 and 13, when the planar shape of the first non-display area NDA1 is a square, one first-1 line LN1-1 may be provided and two first-2 lines LN1-2 may be provided.

The first non-display area NDA1 may include a first-1 non-display area NDA1-1 and a first-2 non-display area NDA1-2. The first-1 non-display area NDA1-1 may be provided in a triangular shape with two sides of the first-2 line LN1-2 and a portion of the first-1 line LN1-1 extending from the first-2 line LN1-2. The first-2 non-display area NDA1-2 may be an area that does not overlap the first-1 non-display area NDA1-1 among the first non-display area NDA1. In an embodiment, as illustrated in FIGS. 12 and 13, the first non-display area NDA1 may include two first-1 non-display areas NDA1-1 and one first-2 non-display area NDA1-2, for example. As illustrated in FIG. 4, when the connection circuit portion CP is bent, the stress applied to the display panel DP in a third direction (e.g., a z-axis direction) may be greatest at a position overlapping the first-1 non-display area NDA1-1.

The first inorganic layer IL1 may be disposed on the substrate 100. In detail, the first-2 inorganic layer IL1-2 may be disposed on the first-1 inorganic layer IL1-1, and the first-3 inorganic layer IL1-3 may be disposed on the first-2 inorganic layer IL1-2. The first organic layer OL1 may be disposed on the first inorganic layer IL1.

The pad portion PD may be disposed in the first non-display area NDA1 (in detail, the first-2 non-display area NDA1-2). The pad portion PD may include the plurality of pad terminals 514 and the plurality of conductive protective layers 515. The pad terminals 514 are disposed on the first organic layer OL1 and may be connected to the corresponding connection wire CW through contact holes penetrating the first organic layer OL1. The pad terminals 514 may be spaced apart along the first direction (e.g., the x-axis direction). The edge of each pad terminal 514 may be covered by the protective layer 400. A portion of the upper surface of each of the pad terminals 514 may be exposed from the protective layer 400. The conductive protective layer 515 may be disposed on the upper surface of the exposed pad terminal 514.

The connection circuit portion CP may be disposed on the substrate 100. The connection circuit portion CP may be a chip on film (“COF”). The connection circuit portion CP may include the connection circuit board 600 including or consisting of a flexible film, and the driving terminal portion 700 disposed on the connection circuit board 600. The driving terminal portion 700 may be disposed to face the pad portion PD and may include the plurality of driving terminals 710. The driving terminals 710 may include at least one conductive layer, e.g., a copper material. An additional conductive layer (not shown), e.g., a tin layer, may be further disposed on an outer surface of the driving terminals 710. The material for the driving terminals 710 is not limited thereto, and the driving terminals 710 may employ any material having superior conductivity. The driving terminals 710 may be spaced apart in the first direction (e.g., the x-axis direction).

The driving terminal portion 700 may be electrically connected to each pad portion PD. In an embodiment, the driving terminal portion 700 and the pad terminal 514 may be connected in the third direction (e.g., the z-axis direction), for example. As shown in FIGS. 10 and 11, the connection portion CNP that electrically connects the driving terminal portion 700 and the pad terminal 514 to each other may be disposed between the driving terminal portion 700 and the pad terminal 514. In another embodiment, the driving terminal portion 700 and the pad terminal 514 may be directly connected to each other. In the following description, explanations are provided on the assumption that the connection portion CNP is disposed between the driving terminal portion 700 and the pad terminal 514.

The connection portion CNP may be a conductive film that allows current to flow in a thickness direction (e.g., the z-axis direction) and is insulating in a width direction (e.g., the y-axis direction) or length direction (e.g., the x-axis direction). In an embodiment, the connection portion CNP may be an anisotropic conductive film (“ACF”). The connection portion CNP may include a conductive particle 791, such as a conductive ball, that forms an electrical path between the pad portion PD and the driving terminal portion 700, and an insulating resin 792 that fixes the conductive particle 791 in place to improve connection reliability.

When the pad portion PD and the driving terminal portion 700 are pressed by a pressurizing device such as a hot bar that utilizes heat and pressure, the pad portion PD may be electrically connected to the driving terminal portion 700 via the conductive particle 791. The insulating resin 792 is distributed outside the area where the pad terminal 514 and the driving terminal portion 700 are connected, so that a pair of pad terminals 514 and driving terminals 710 corresponding to the third direction (e.g., the z-axis direction) and another pair of pad terminals 514 and driving terminals 710 next (adjacent) thereto may be insulated from each other.

The display panel DP may include a first alignment mark MK1. The first alignment mark MK1 may be disposed in the first non-display area NDA1 (in detail, the first-2 non-display area NDA1-2). The first alignment mark MK1 may be disposed so as not to overlap the pad portion PD. The connection circuit portion CP may include a second alignment mark MK2. The second alignment mark MK2 may be disposed at a position corresponding to the first alignment mark MK1. As illustrated in FIG. 13, when the display panel DP and the connection circuit portion CP are connected, the first alignment mark MK1 and the second alignment mark MK2 may overlap each other. In the alignment process, the display panel DP and the connection circuit portion CP are disposed so that the first alignment mark MK1 and the second alignment mark MK2 overlap each other in a plan view, and then the display panel DP and the connection circuit portion CP may be connected.

As illustrated in FIGS. 10 and 11, a first groove area GR1 may be defined in the first inorganic layer IL1. At least a portion of the first organic layer OL1 may be accommodated in the first groove area GR1. The first groove area GR1 may have a rough structure having a predetermined pattern. The first groove area GR1 may serve to improve interfacial adhesion by increasing the contact area with the first organic layer OL1. In addition, the first groove area GR1 provides a mechanical interlocking effect that may reduce delamination caused by external stress or temperature changes. Accordingly, the adhesion between the first inorganic layer IL1 and the first organic layer OL1 may be improved, and the overall structural stability may be increased.

As shown in FIGS. 12 and 13, the first groove area GR1 may be provided in a multiple number and overlap the first line LN1. At least one of the first groove areas GR1 may overlap the first-1 line LN1-1. The first groove area GR1 may be disposed to overlap each of the first non-display area NDA1 and the second non-display area NDA2. The first groove area GR1 may be spaced apart from the pad portion PD. In an embodiment, in a plan view, the first groove area GR1 may be provided in a straight line shape extending in a direction from the first non-display area NDA1 toward the second non-display area NDA2, for example.

However, this is an illustrative embodiment, and the structure of the first groove area GR1 may be designed in various ways depending on desired purposes. The shape, depth and pattern of the first groove area GR1 may be optimized and, e.g., may be formed as a fine trench or protrusion. In an embodiment, as illustrated in FIG. 12, at least two of the plurality of first groove areas GR1 may differ from each other in size, for example. In FIGS. 10 and 11, an upper surface of the first organic layer OL1 overlapping the first groove area GR1 is depicted as being flat, but the upper surface of the first organic layer OL1 may be curved depending on the degree of exposure of the first organic layer OL1 in the process of patterning the first organic layer OL1.

The first groove areas GR1 overlapping the first-1 line LN1-1 may be spaced apart from each other along the first direction (e.g., the x-axis direction). At least one of the first groove areas GR1 may overlap the first-2 line LN1-2. The first groove areas GR1 overlapping the first-2 line LN1-2 may be spaced apart from each other along the second direction (e.g., the y-axis direction). In this structure, the first groove area GR1 may be disposed in the first-1 non-display area NDA1-1 in which the stress applied to the display panel DP is the highest. Accordingly, the phenomenon of damage to the display panel DP due to stress applied to the display panel DP due to the elasticity of the connection circuit portion CP may be reduced.

As illustrated in FIGS. 10 and 11, a second groove area GR2 may be defined in the first inorganic layer IL1. The second groove area GR2 may have a rough structure with a predetermined pattern. At least a portion of the first organic layer OL1 may be accommodated in the second groove area GR2. The second groove area GR2 may serve to improve interfacial adhesion by increasing the contact area with the first organic layer OL1. In addition, the second groove area GR2 provides a mechanical bonding effect that may reduce delamination between layers due to external stress or temperature changes. Accordingly, the adhesion between the first inorganic layer IL1 and the first organic layer OL1 may be improved, and the overall structural stability may be increased.

As shown in FIGS. 12 and 13, the second groove area GR2 may be defined inside the first non-display area NDA1. In an embodiment, the second groove area GR2 may be disposed in the first-1 non-display area NDA1-1, for example. The second groove area GR2 may be spaced apart from the pad portion PD. In an embodiment, in a plan view, the second groove area GR2 may be provided in the shape of a square dot, for example.

However, this is an illustrative embodiment, and the structure of the second groove area GR2 may be designed in various ways depending on desired purposes. The shape, depth and pattern of the second groove area GR2 may be optimized and, e.g., may be formed as a fine trench or protrusion.

In this structure, the second groove area GR2 may be disposed in the first-1 non-display area NDA1-1 where the stress applied to the display panel DP is the highest. Accordingly, the phenomenon of damage to the display panel DP due to stress applied to the display panel DP due to the elasticity of the connection circuit portion CP may be reduced.

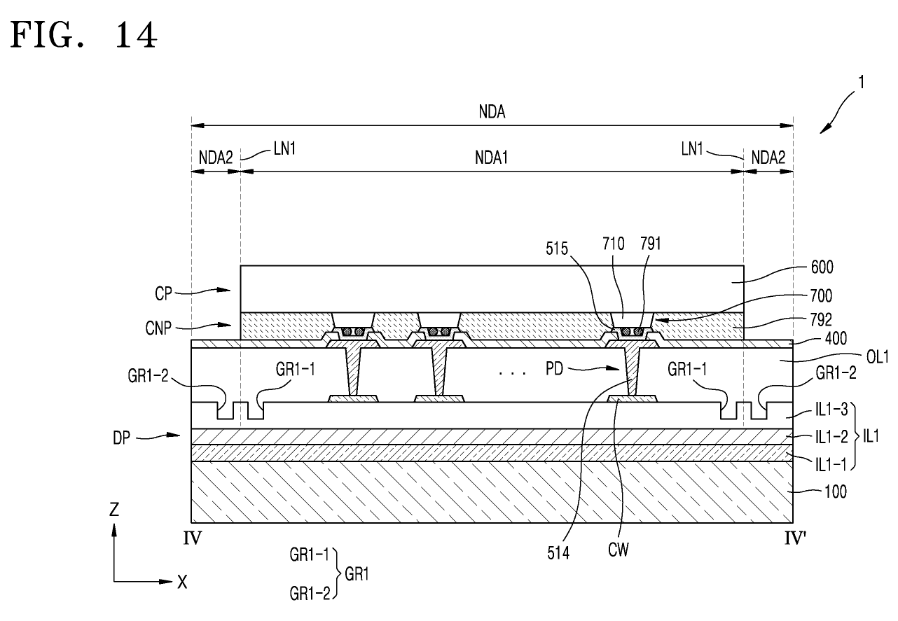

FIG. 14 is a cross-sectional view schematically illustrating an embodiment of a portion of the display device 1.

In detail, FIG. 14 is a cross-sectional view of the display device 1 along line IV-IV' of FIG. 1. FIG. 14 is a drawing showing a state in which the connection circuit portion CP is connected to the display panel DP.

In FIG. 14, like reference numerals in FIGS. 10 to 13 denote like elements, and redundant descriptions thereof are omitted.

Referring to FIG. 14, the display device 1 may include the display panel DP, the connection circuit portion CP, and the connection portion CNP.

The non-display area NDA may include the first non-display area NDA1 and the second non-display area NDA2. In a plan view, the boundary between the first non-display area NDA1 and the second non-display area NDA2 may be defined as the first line LN1. The first non-display area NDA1 may include the first-1 non-display area NDA1-1 and the first-2 non-display area NDA1-2.

The first inorganic layer IL1 may be disposed on the substrate 100. In detail, the first-2 inorganic layer IL1-2 may be disposed on the first-1 inorganic layer IL1-1, and the first-3 inorganic layer IL1-3 may be disposed on the first-2 inorganic layer IL1-2. The first organic layer OL1 may be disposed on the first inorganic layer IL1.

The pad portion PD may be disposed in the first non-display area NDA1 (in detail, the first-2 non-display area NDA1-2). The pad portion PD may include the plurality of pad terminals 514 and the plurality of conductive protective layers 515. The pad terminals 514 are disposed on the first organic layer OL1 and may be connected to the corresponding connection wire CW through contact holes penetrating the first organic layer OL1. The edge of each pad terminal 514 may be covered with the protective layer 400. The portion of the upper surface of each of the pad terminals 514 may be exposed from the protective layer 400. The conductive protective layer 515 may be disposed on the upper surface of the exposed pad terminal 514.

The connection circuit portion CP may be disposed on the substrate 100. The connection circuit portion CP may include the connection circuit board 600 and the driving terminal portion 700 disposed on the connection circuit board 600. The driving terminal portion 700 may be disposed to face the pad portion PD and may include the plurality of driving terminals 710.

Between the driving terminal portion 700 and the pad terminal 514, the connection portion CNP that electrically connects the driving terminal portion 700 and the pad terminal 514 to each other may be disposed. The connection portion CNP may include the conductive particle 791, such as a conductive ball, that forms an electrical path between the pad portion PD and the driving terminal portion 700, and the insulating resin 792 that fixes the conductive particle 791 in place to improve connection reliability.

As illustrated in FIGS. 10 and 11, the first groove area GR1 overlapping the first line LN1 may be defined in the first inorganic layer IL1. At least a portion of the first organic layer OL1 may be accommodated in the first groove area GR1. The first groove area GR1 may have a rough structure having a predetermined pattern. The first groove area GR1 may serve to improve interfacial adhesion by increasing the contact area with the first organic layer OL1.

The first groove area GR1 may include a first-1 groove area GR1-1 and a first-2 groove area GR1-2 connected to the first-1 groove area GR1-1. The first-1 groove area GR1-1 may be disposed in the first non-display area NDA1, and the first-2 groove area GR1-2 may be disposed in the second non-display area NDA2. The first-1 groove area GR1-1 and the first-2 groove area GR1-2 that are connected to each other may be provided in a straight line shape extending in a direction from the first non-display area NDA1 toward the second non-display area NDA2. However, this is an illustrative embodiment, and the structures of the first-1 groove area GR1-1 and the first-2 groove area GR1-2 may be designed in various ways depending on the desired purposes.

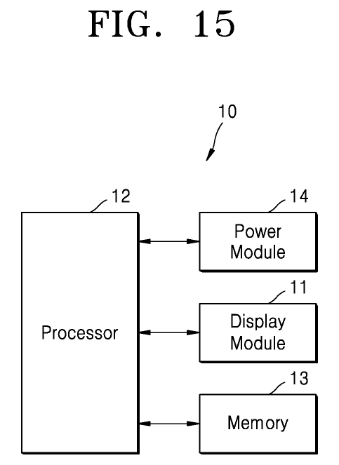

FIG. 15 is a block diagram of an embodiment of an electronic device 10.

Referring to FIG. 15, the electronic device 10 in an embodiment may include a display module 11, a processor 12, a memory 13, and a power module 14.

The processor 12 may include at least one of a central processing unit (“CPU”), an application processor (“AP”), a graphics processing unit (“GPU”), a communication processor (“CP”), an image signal processor (“ISP”), and a controller.

Data information desired for the operation of the processor 12 or the display module 11 may be stored in the memory 13. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power desired for the operation of the electronic device 10.

At least one of the components of the above-described electronic device 10 may be included in the display device according to the above-described embodiments. Additionally, some of the individual modules functionally included within a module may be included within the display device, while others may be provided separately from the display device. In an embodiment, the display device may include the display module 11, and the processor 12, a memory 13 and a power module 14 may be provided in the form of other devices within the electronic device 10 other than the display device, for example.

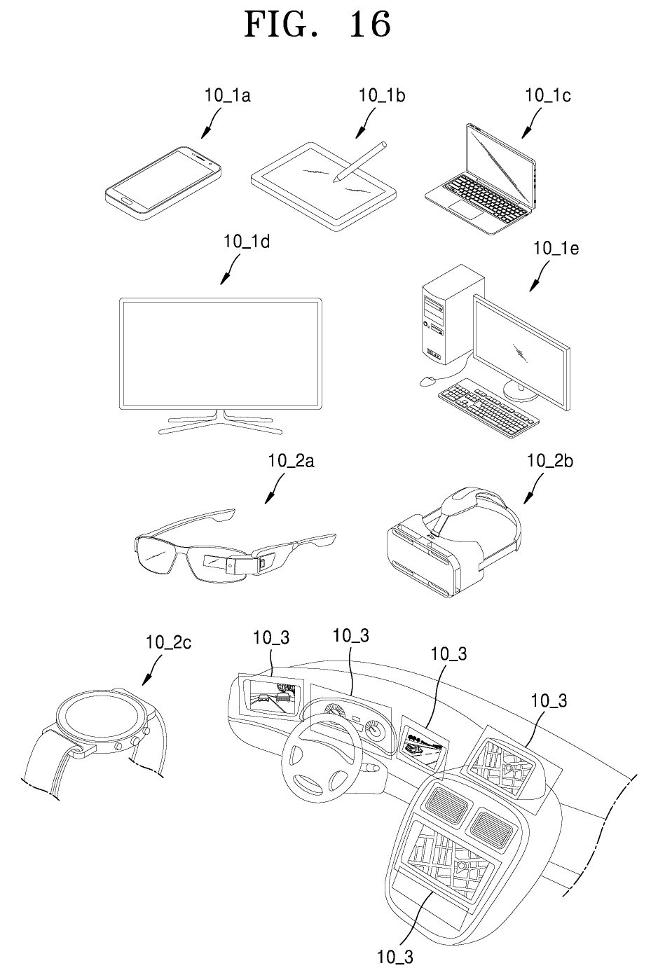

FIG. 16 is a perspective view schematically illustrating an embodiment of the electronic device.

Referring to FIG. 16, various electronic devices to which display devices in embodiments are applied may include not only image display electronic devices such as a smart phone 10_1a, a tablet personal computer 10_1b, a laptop 10_1c, a television (“TV”) 10_1d, and a desk monitor 10_1e, but also wearable electronic devices including display modules, such as smart glasses 10_2a, a head mounted display 10_2b, and a smart watch 10_2c, and vehicle electronic devices 10_3 including display modules, such as a center information display (“CID”) and a room mirror display disposed on an instrument cluster, center fascia, or dashboard of an automobile.

By embodiments, the durability of a display device may be improved.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display device comprising:
a display panel including:
a display area; and
a non-display area including:
a first non-display area; and
a second non-display area;
a substrate;
a first inorganic layer disposed on the substrate and including a first groove area; and
a first organic layer disposed on the first inorganic layer and contacting the first inorganic layer; and
a connection circuit portion electrically connected to the display panel and overlapping the first non-display area, and
wherein the first groove area overlaps a first line which is a boundary line between the first non-display area and the second non-display area.

2. The display device of claim 1, wherein
the first line includes:
a first-1 line extending in a first direction parallel to a bending axis along which the connection circuit portion is bent, and
a first-2 line extending from the first-1 line in a second direction intersecting the first direction, and
the first groove area overlaps the first-2 line.

3. The display device of claim 2, wherein
the first groove area is provided in plural, and
a plurality of first groove areas are spaced apart from each other along the second direction at positions overlapping the first-2 line.

4. The display device of claim 3, wherein at least two of the plurality of first groove areas differ in size from each other.

5. The display device of claim 1, wherein the first groove area includes a first-1 groove area and a first-2 groove area connected to the first-1 groove area.

6. The display device of claim 5, wherein the first-1 groove area is disposed in the first non-display area, and the first-2 groove area is disposed in the second non-display area.

7. The display device of claim 1, wherein the first inorganic layer further includes a second groove area defined inside the first non-display area.

8. The display device of claim 1, wherein
the display panel further includes:
a driving transistor disposed on the substrate and overlapping the display area; and
a light-emitting element which is disposed on the first organic layer, overlaps the display area and is electrically connected to the driving transistor.

9. The display device of claim 8, wherein
the driving transistor includes:
a semiconductor layer disposed within the first inorganic layer; and
a gate electrode disposed between the first inorganic layer and the first organic layer.

10. The display device of claim 1, wherein
the display panel further includes a pad portion disposed in the first non-display area, spaced apart from the first groove area and electrically connected to the connection circuit portion.

11. An electronic device comprising:
a display panel including:
a display area; and
a non-display area including:
a first non-display area;
a second non-display area;
a substrate;
a first inorganic layer which is disposed on the substrate and in which a first groove area is defined; and
a first organic layer disposed on the first inorganic layer and contacting the first inorganic layer; and
a connection circuit portion electrically connected to the display panel and overlapping the first non-display area,
wherein the first groove area overlaps each of the first non-display area and the second non-display area.

12. The electronic device of claim 11, wherein the first groove area includes a first-1 groove area and a first-2 groove area connected to the first-1 groove area.

13. The electronic device of claim 12, wherein the first-1 groove area is disposed in the first non-display area, and the first-2 groove area is disposed in the second non-display area.

14. The electronic device of claim 11, wherein
a second groove area overlapping the first non-display area and non-overlapping the second non-display area is defined in the first inorganic layer.

15. The electronic device of claim 11, wherein
the display panel further includes
a driving transistor disposed on the substrate and overlapping the display area, and
a light-emitting element which is disposed on the first organic layer, overlaps the display area and is electrically connected to the driving transistor.

16. The electronic device of claim 15, wherein
the driving transistor includes:
a semiconductor layer disposed within the first inorganic layer, and
a gate electrode disposed between the first inorganic layer and the first organic layer.

17. The electronic device of claim 11, wherein the first groove area overlaps a first line which is a boundary line between the first non-display area and the second non-display area.

18. The electronic device of claim 17, wherein
the first line includes:
a first-1 line extending in a first direction parallel to a bending axis along which the connection circuit portion is bent, and
a first-2 line extending from the first-1 line in a second direction intersecting the first direction, and
the first groove area overlaps the first-2 line.

19. The electronic device of claim 18, wherein
the first groove area is provided in plural, and
a plurality of first groove areas are spaced apart from each other along the second direction at positions overlapping the first-2 line.

20. The electronic device of claim 11, wherein
the display panel further includes a pad portion which is disposed in the first non-display area, spaced apart from the first groove area and is electrically connected to the connection circuit portion.
